(19) United States
(12) Patent Application Publication
(10) Pub. No.: US 2003/0059687 A1
(43) Pub. Date: Mar. 27, 2003

(54) Anti-resonance mask for off-axis photolithography

(75) Inventor: El-Badawy El-Sharawy, Gilbert, AZ (US)

Correspondence Address: Squire, Sanders & Dempsey L.L.P., Two Renaissance Square, Suite 2700, 40 North Central Avenue, Phoenix, AZ, 85004-4498, US

(73) Assignee: National Scientific Corporation

(21) Appl. No.: 09/960,896

(22) Filed: Sep. 21, 2001

(51) Int. Cl. G03F 9/00; G03B 27/42; G03C 5/00

(52) U.S. Cl. 430/5; 430/311; 430/322; 355/53

(57) ABSTRACT

A lithographic mask for use in an off-axis illumination system is provided. The mask includes a transparent substrate and a first patterned layer of an opaque material proximate to a first side of the transparent substrate. A second patterned layer is formed over the first patterned layer. The second patterned layer comprising a dielectric material configured to phase shift an exposure energy directed towards the mask. Over the second patterned layer a third patterned layer is formed. The third patterned layer is manufactured from an opaque material.

### TECHNICAL FIELD

This invention relates to the field of photolithography and, more specifically, to an anti-resonance mask for off-axis photolithography.

### BACKGROUND OF THE INVENTION

Photolithography is used extensively in the manufacture of semiconductor integrated circuits. In a typical photolithographic process energy, such as ultraviolet light, is projected through a mask and onto a layer of light sensitive material, known as resist, deposited on a semiconductor wafer. In a typical embodiment, the mask has a pattern formed on it comprising light blocking material applied in certain areas over a light transmissive substrate. The pattern is a layout of a layer or part of a layer of an integrated circuit to be formed on the semiconductor wafer. This pattern is projected on to the resist covered semiconductor wafer. The areas where the blocking material is applied will not receive any of the exposure energy while areas where the light passes through will receive energy from the illumination source. The exposure to the illumination source will change the chemical make-up of the resist. Depending on the type of resist, this will either make it easy to remove (positive resist) or hard to remove (negative resist). If positive resist is used, the exposed resist is removed and the wafer undergoes further processing such as etching or ion deposition. If negative resist is used, the unexposed resist is removed and the wafer undergoes further processing.

As the need to form smaller features on a silicon wafer increases, so does the need to develop techniques that allow for the formation of these features with a high resolution and a large depth of focus. Resolution is the ability to project small features on the mask to the wafer. Depth of focus is the ability to reproduce the mask image on a wafer as the wafer varies in its distance from the mask. It is well known that resolution has been enhanced by the use of optics with a high numerical aperture and by the use of short wavelengths of light (deep ultraviolet light) as the illumination source. Unfortunately, these techniques tend to decrease the depth of focus.

One proposed solution is the use of phase shifting masks. Phase shifting masks use materials in certain places that are at least partial light transmissive and cause light that passes through to be shifted 180 degrees in phase. Typically, the material is placed near the edges of the mask pattern to enhance the edge contrast. This results in both a higher resolution and greater depth of focus as compared to conventional masks. One type of phase shifting mask is the attenuating phase shifting mask. This mask both attenuates the intensity and shifts the phase of incident light.

While phase shifting masks represent an improvement over conventional binary masks, they also have certain drawbacks. First, for attenuating phase shifting masks, the attenuation capabilities are dependent on the wavelength of the illumination source. Consequently, materials that may attenuate a certain wavelength may act as a total block when light of a smaller wavelength is used. Also, phase shifting masks provide poor resolution for periodic structures, especially when a relatively small mask opening is adjacent to a larger mask opening. Also, conventional phase shifting masks are not compatible with off-axis illumination systems. In an off-axis illumination system, light is incident on a mask at an angle from both the left side of the mask and the right side of the mask. In an on-axis illumination system, substantially all the incident light enters the mask and passes through the mask openings at the same angle. Off-axis illumination systems provide a greater depth of field and resolution as compared to on-axis systems. The incompatibility of conventional, attenuating phase shifting masks limits the usefulness of phase shifting masks in obtaining further improvements to resolution and depth of focus. Without the present invention the limited resolution and depth of focus prohibit further advances in the production of complex circuits, for example microcomputer circuits, analog signal processors and communication circuits.

### SUMMARY OF THE INVENTION

Thus, a need has arisen for an anti-resonance mask for photolithography that overcomes disadvantages associated with previous masks.

In one embodiment of the present invention, a lithographic mask for use in an off-axis illumination includes a transparent substrate and a first layer of an opaque material proximate to a first side of the transparent substrate. A second layer is formed over the first patterned layer. The second layer includes a dielectric material configured to phase shift light passing through and scattering from the second layer. Over the second layer a third layer is formed. The third layer is manufactured from an opaque material. Etching through the third layer, the second layer and the first layer forms at least one mask opening.

In another embodiment, a system for projecting a mask pattern on a semiconductor wafer includes an off-axis illumination means for producing a source of off-axis illumination and an anti-resonance mask that receives the off-axis illumination. The mask includes a transparent substrate having a first layer of an opaque material formed over it. A second layer of dielectric material is formed over the first layer. The second layer shifts the phase of incident light passing through it. Over the second layer a third layer of an opaque material is formed. At least one mask opening is formed by etching through the third layer, the second layer and the first layer. A projection means optically coupled to the mask projects an image of the mask on to the silicon wafer.

A method of forming an anti-resonance mask according to various aspects of the present invention may be used in an off-axis illumination system is disclosed. Initially, a transparent substrate is provided. Next a first layer of opaque material is formed over the transparent substrate. Then, a layer of dielectric material is formed over the first layer of opaque material. A second layer of opaque material is formed over the layer of dielectric material. Then, a pattern on the mask is formed by etching through the second layer of opaque material, the layer of dielectric material and the first layer of opaque material such that the off-axis illumination may pass through an opening formed by the etching, may scatter off of the layer of dielectric material and pass through the opening or, may scatter off of the first layer and the second layer and cancel a portion of the off-axis illumination.

Technical benefits of the present invention include providing an anti-resonance mask that has a high resolution and depth of focus due to the use of an off-axis illumination system and the properties of a dielectric layer formed between two opaque layers. Also, due to the simplicity in structure the mask of the present invention is easy to manufacture and repair. Other technical benefits are apparent from the following descriptions, illustrations and claims.

### BRIEF DESCRIPTION OF THE DRAWINGS

The drawings further illustrate the present invention and, together with the detailed description of the invention, serve to explain the principles of the present invention, and wherein:

FIG. 1 is a schematic diagram of an off-axis photolithographic system;

FIG. 2 is a cross section of a portion of an anti-resonance mask with a single opening for use in the system of FIG. 1;

FIG. 3 is a graph of the electric field near the mask for the anti-resonance mask of FIG. 2;

FIG. 4 is a graph of the illumination intensity at the wafer for the anti-resonance mask of FIG. 2;

FIG. 5 is a cross section of a portion of an anti-resonance mask with multiple opening for use in the system of FIG. 1;

FIG. 6 is a graph of the electric field near the mask for the anti-resonance mask of FIG. 5; and

FIG. 7 is a graph of the illumination intensity at the wafer for the anti-resonance mask of FIG.5.

### DETAILED DESCRIPTION OF THE DRAWINGS

The present invention is adapted for use in an off-axial illumination system. Various types of off-axial illumination system exist and are suited for use with the present invention. For example, FIG. 1 is a simplified illustration of an exemplary conventional off-axis illumination photolithographic system 100 for use with the mask of the present invention. Photolithographic system 100 includes an illumination source 102, a beam splitter 104, a prism 106, a fly's eye lens 108, a mask 110, a projection lens 112 and a wafer 114. A number of mirrors 103 direct the beam from the illumination source to the next component in the system.

Illumination source 102 may be any coherent or incoherent source of light such as an ultraviolet light source produced, for example, by an excimer laser such as a KrF excimer laser, which produces a 248 nm wavelength light. The choice of illumination source 102 is typically based on the desired size of the features to be formed on wafer 110. Smaller feature sizes typically require shorter wavelengths of light to be used as an illumination source. Other usable illumination sources include xenon fluoride (XeF), which produces a 350 nm wavelength light, argon fluoride (ArF), which produces a 193 nm wavelength of light, and fluoride (F₂) that produces a 157 nm wavelength of light.

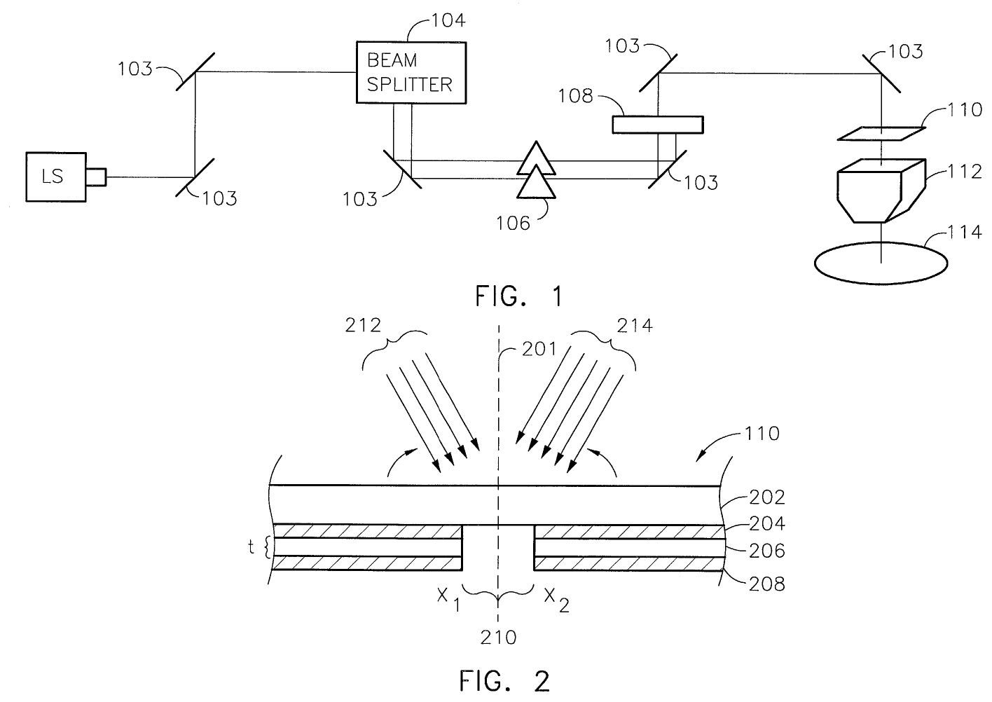

Beam splitter 104 receives a single beam of light and divides the beam into two or more beams. Each prism 106 takes one of the multiple beams of light and overlaps them for presentation to the fly's eye lens 108. Typically, there is one prism 106 for each beam of light exiting the beam splitter 104. Fly's eye lens 108 is a two dimensional array of a spherical lens. Mask 110 is a novel mask having a pattern etched on one side representing a circuit design or the like. Mask 110 will be discussed in further detail in conjunction with FIGS. 2-7. Projection lens 112 contains optics to project the image of the mask's pattern on to wafer 114. Projection lens 112 may either produce an image of the mask pattern on the wafer that is the same size as the mask pattern or may produce an image on wafer 1 14 that is smaller than the mask pattern. Wafer 114 may be a conventional semiconductor wafer that has a layer of resist formed on the surface.

In operation, illumination source 102 produces a single beam of light. The single beam of light passes to beam splitter 104. Beam splitter 104 divides the single beam of light into two or more beams of light. Each of the multiple beams of light passes through prisms 106 where they are made to overlap. The overlapping beams of light then passes through fly's eye lens 108. By adjusting fly's eye lens 108, a selected off-axis light source profile (e.g. a quadruple light source or a spherical light source) is formed. Additionally, fly's eye lens 108 provides a smoother, more tapered light source that tends to increase the depth of focus by avoiding a rapid drop in illumination intensity. The off-axis light from fly's eye lens 108 passes through mask 110 to projection lens 112. Projection lens 112 projects an image of the mask's pattern on to the resist on wafer 114. The projected image of the mask's pattern exposes energy from the light sources to certain areas of the wafer 114 and does not expose the wafer 114 to energy from the light source in other areas. Depending on the type of resist used, either the exposed resist is removed or the unexposed resist is removed. The wafer 114 is then subject to further processing such as ion implantation or etching.

FIG. 2 is a cross section of a portion of the anti-resonance mask 110 with a single opening 210 representing part of a circuit pattern formed on mask 110. Mask 110 comprises a substrate 202 with a first layer 204 of an opaque material formed on the substrate 202. A second layer 206 of a dielectric material is formed over the first layer 204. A third layer 208 of opaque material is formed over the second layer 206. The embodiment of FIG. 2 shows a single opening 210 etched through the first, second and third layers 204, 206 and 208 using conventional etching techniques.

The opening 210 begins at X₁ and ends at X₂. The size of opening 210 depends on the size of the feature to be formed on wafer 112. In some situations, the size of opening 210 will be the same size as the desired feature on wafer 112. In other embodiments, projection lens 112 is used to reduce the image of the opening 210 by a factor of 2 to 1 or 4 to 1. Single opening 210 represents the use of mask 110 to produce isolate structures on wafer 114. Isolated feature are features are the wafer that are apart from other features.

The choice of materials for substrate 202 depends on the wavelength of the illumination source used. The transparency of a material is dependent on the wavelength of light that passes through the material. Materials that may be transparent at one wavelength may be only partially or not at all transparent at a different wavelength. For example, a quartz substrate may be used for wavelengths of light between 150 and 250 nanometers. Calcium fluoride may be used for wavelengths less than 180 nanometers. Fused silica is useful for wavelengths of light greater than 200 nanometers. The thickness of substrate 202 is chosen to sufficiently thick to support the additional layers and is independent of the wavelength of light used. For example, the thickness of the substrate may range from 0.5 to 5 millimeters.

First layer 204 and third layer 208 are preferably made from an opaque metal such as chromium or aluminum. First layer 204 and third layer 208 are designed to be thick enough to avoid the formation of standing waves. The thickness required is a function of the incident light. To the formation of standing waves the thickness needs to be at least as thick as one-fourth of the wavelength of the incident light used. For an argon fluoride illumination source of 193 nm the thickness of first layer 204 and second layer 206 should be 48 nm or thicker.

The light scattering off of second layer 206 forms side lobes on either side of the desired central light intensity peak. In order to increase resolution, it is desirable to minimize side lobe formation. Thus, it is desirable to both phase shift and attenuate the light incident on second layer 206.

To attenuate the scattered light, second layer 206 is designed to be an anti-resonance layer. An anti-resonance layer suppresses the electric field between first layer 204 and third layer 208. Also, an anti-resonance layer reduces coupling between nearby openings in a mask. To form the anti-resonance layers the physical thickness, t, of second layer 206 is chosen such that t=(nλ)/4, where n is an odd integer and λ is the wavelength of the incident light. As mentioned previously, second layer 206 causes incident light to undergo a phase shift. For optimal results, the phase of light that passes through second layer 206 needs to be 180 degrees greater than the phase of the light that passes opening 210. The refractive index of the dielectric material is also equal to the electrical thickness of the material divided by its physical thickness. The refractive index is a material property equal to the reciprocal of the relative speed of light in the medium. Taking the anti-resonance condition, the phase shift requirement and the refractive index requirement into consideration, appropriate material for second layer 206 can be chosen. Materials that fit the anti-resonance criteria and have an appropriate index of refraction include silicon nitride, calcium fluoride and silicon oxide. The physical thickness of the second layer 206 depends on the wavelength of the light source as explained previously. As an example, for a 193 nm light source (ArF source), a silicon oxide dielectric layer with a refractive index of 1.4 has a physical thickness of approximately 241 nm thick.

In operation, light from an off-axis illumination source impinges on mask 110. In an off-axis illumination source light impinges the mask at an angle with respect to an axis 201 normal to the surface of the mask. The incident light comprises both left side incident light 212 and right hand incident light 214. When left hand side and right hand side incident light 212, 214 impinges on mask 110 one of several things can happen. First layer 204 may block the incident light. The incident light may pass through the opening of the mask 10. The incident light may scatter off of first layer 204. The incident light may scatter off of third layer 208. The light scattering off of third layer 208 will typically be one hundred eighty degrees out of phase with the light scattering off of second layer due to the difference in path length of the light. This will result in the scattered light from first layer 204 canceling with the scattered light of third layer 208. The incident light can also scatter off of second layer 206. The light scattering off of second layer 206 is both attenuated and phase-shifted.

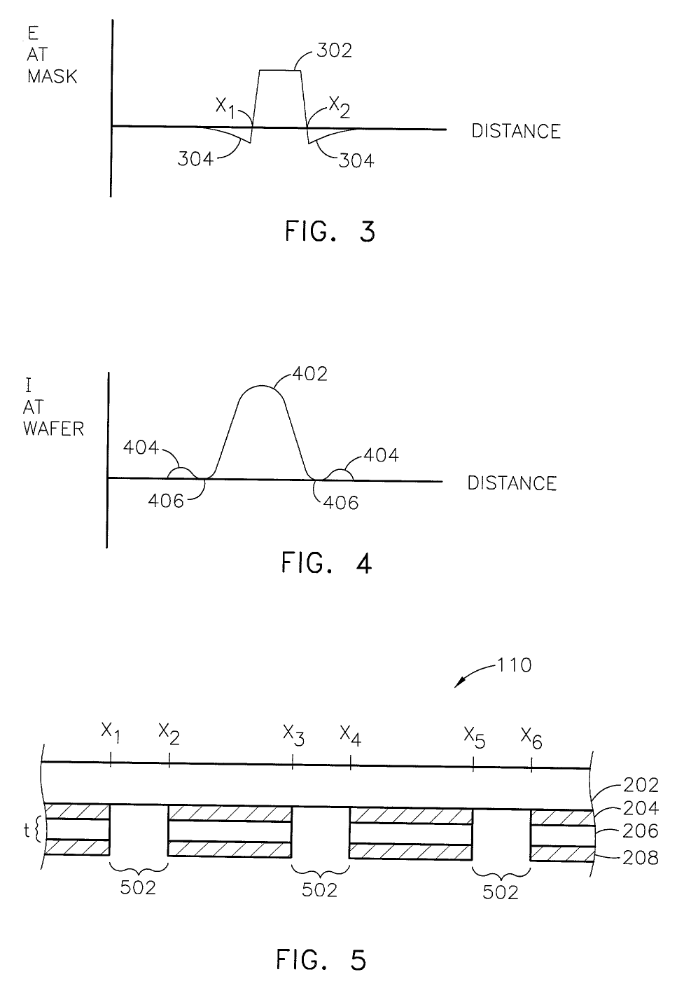

FIG. 3 illustrates the electric field distribution 300 at the mask I 1O. The vertical axis is the electric field intensity. The horizontal axis is the distance across the mask from one edge to another. The electric field distribution at the mask 110 shows a peak 302 where the light passes through opening 210. Peak 302 begins at point X₁ corresponding to the beginning of opening 210 and ends at point X₂ corresponding to the end of opening 210. Minimal areas 304 are formed where the light impinges on and scatters off of the dielectric material of second layer 206. The shape of peak 302 is slightly tapered due to the effects of the off-axis illumination passing through opening 210 as opposed to passing straight through the opening. The amount of taper depends on the angle of the off-axis illumination used, the width of the opening and the thickness of first layer 204, second layer 206 and third layer 208. The percent taper can be found by multiplying the sum of the thickness of all three layers by the tangent of the angle of illumination and divided buy the size of the opening. The tapered profile increases depth of field by providing a gradual drop off in electric field intensity as a function of distance across the opening 210. If the pulse were rectangular with no taper then the electrical field intensity would drop sharply to zero at the edge of the opening.

FIG. 4 illustrates the light intensity pattern at wafer 114 after passing through the mask of FIG. 2. The vertical axis is the intensity of light. The horizontal axis is the distance across the wafer. The characteristics of the pattern are a high intensity central area 402 corresponding to light passing through the opening 210 in mask 110 with very minimal side lobes 404. Note that the intensity goes to a zero value between side lobes 404 and peak 402. The fact the intensity goes to a zero valve means that there will be two small light areas represented by side lobes 404, on either side of the large light area represented by peak 402 separated by a dark area. The separation allows for greater contrast around the area formed by peak 402. The greater contrast results in a higher resolution than in conventional masks. By choosing a resist that is insensitive to light below a certain intensity level, the effect of the illumination produced by the side lobes 404 is ignored. Had an-axis illumination been used, the resolution would not have been enhanced because there would only be, at best, negligible scattering off of second layer 206. Also, because the openings on mask 110 are formed by simply etching through the first layer, the second layer and the third layer, the anti-resonance mask 110 of the present invention is easier to manufacture and repair than existing masks.

FIG. 5 is a cross section of a portion of the anti-resonance mask 110 with several openings 502 close together. Openings 502 are a circuit pattern that is etched into mask 110 which will be projected onto the wafer. The multiple openings in mask 110 correspond to closely spaced or densely packed features to be produced on the wafer. In FIG. 5, the first opening is between point X₁ and X₂, the second opening is between X₃ and X₄ and the third opening is between X₅ and X₆. Again, mask 110 comprises a substrate 202, of quartz or the like, with a first layer 204 of an opaque material such as chromium. Over the first layer 204, a second layer 206 of a dielectric material is formed. Over the second layer 206 a third layer 208 of an opaque material such as chromium is formed. Then, a number of openings 502 are formed on mask 110.

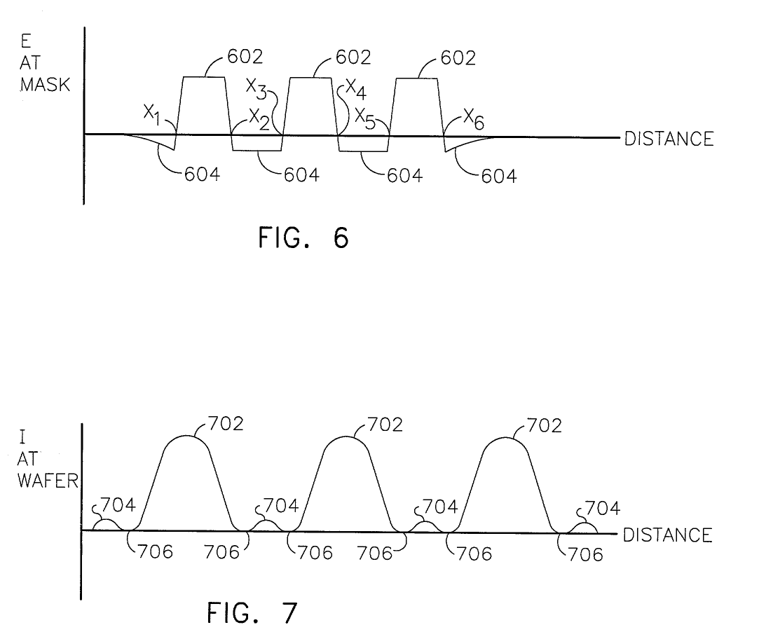

Off-axis light incident on mask 110 can again be blocked by first layer 204, pass through the opening 512, scatter off of second layer 206, or scatter off of third layer 208. The resultant electric field near the mask is shown in FIG. 6. Again, the slightly tapered positive peaks 602 are due primarily to light passing through the openings 512. The smaller areas 604 below the horizontal axis 606 are the contribution due to light passing through and scattering off of second layer 206.

FIG. 7 is a graph of the intensity of light at the wafer for the embodiment of FIG. 5. Again, there are significant intense areas 602 corresponding to the openings 512 in the mask 110 with little side lobes. Also, the intense areas 602 are bordered by areas were the intensity goes to zero. This allows for greater contrast for the intense areas projected on to the wafer and a greater resolution when producing dense features. This illustrates that the novel mask of the present invention is useful for masks used to produce both dense features and isolated features.

Having now described preferred embodiments of the invention modifications and variations may occur to those skilled in the art. The invention is thus not limited to the preferred embodiments, but is instead set forth in the following clauses and legal equivalents thereof.

What is claimed is:

1. A mask illuminated by an off-axis illumination system comprising:
a transparent substrate;
a first layer formed on the transparent substrate, the first layer comprising an opaque material;
a second layer formed over the first layer, the second layer shifting the phase of incident light, the second layer comprising a dielectric material;
a third layer formed over the second layer, the third layer comprising an opaque material; and
at least one opening formed by etching through the third layer, the second layer, and the first layer.

2. The mask of claim 1 wherein the first layer and third layer comprise opaque chromium.

3. The mask of claim 1 wherein the second layer shifts the phase of incident light by one hundred eighty degrees as compared to light passing through the at least one opening.

4. The mask of claim 1 wherein the thickness of the second layer is chosen such that the second layer is an anti-resonance layer.

5. The mask of claim 1 wherein the substrate comprises a material selected from the group consisting of quartz, calcium fluoride, and fused silica.

6. The mask of claim 1 wherein the second layer comprises a material selected from the group consisting silicon nitride, calcium fluoride and silicon oxide.

7. The mask of claim 1 wherein light incident on the at least one opening forms an electric field pattern characterized by a tapered peak, formed primarily by the off-axis illumination passing through the isolated opening, between regions formed by off-axis illumination scattering off of the second layer.

8. The mask of claim 1 wherein an image of the mask is produced on a silicon wafer covered with a resist by passing a light through the mask.

9. A system for projecting a pattern onto a semiconductor wafer comprising:
an illumination means for producing off-axis illumination;
a mask that receives the off-axis illumination, the mask comprising:
a transparent substrate;
a first layer formed on the transparent substrate;
a second layer formed over the first layer, the second shifting the phase of incident light passing through the second layer, the thickness of the second layer chosen such that the second layer is an anti-resonance layer;
a third layer formed over the second layer; and
at least one opening formed by etching through the third layer, the second layer and the first layer; and
a projection means for projecting an image of the mask, formed by the off-axis illumination passing through the mask, on to the semiconductor wafer.

10. The system of claim 9 wherein the first layer and third layer comprise opaque chromium.

11. The system of claim 9 wherein the second layer shifts the phase of incident light one hundred eighty degrees.

12. The system of claim 9 wherein the substrate comprises a material selected from the group consisting of quartz, calcium fluoride, and fused silica.

13. The system of claim 9 wherein the second layer comprises a material selected from the group consisting silicon nitride, calcium fluoride and silicon oxide.

14. The system of claim 9 further comprising a fly's eye lens coupled between the illumination means and the mask producing a variety of off-axis light patterns that are passed through the mask, forming an image of the mask on the semiconductor wafer.

15. A method of forming an anti-resonance mask for use in an off-axis illumination system comprising:
providing a transparent substrate;
forming a first layer of opaque material over the transparent substrate;
forming a layer of dielectric material over the first layer of opaque material;
forming a second layer of opaque material over the layer of dielectric material; and
forming a pattern on the mask by etching through the second layer of opaque material, the layer of dielectric material and the first layer of opaque material such that the off-axis illumination may pass through an opening formed by the etching, may scatter off of the layer of dielectric material and pass through the opening or, may scatter off of the first layer and the second layer and cancel each other out.

16. The method of claim 15 wherein the step of forming a second layer further comprises forming a second layer of dielectric material to shift the phase of light scattering of off the second layer.

17. The method of claim 15 wherein the step of forming a second layer further comprises forming a second layer of sufficient thickness to attenuate light by acting as an anti-resonance layer.

18. A method for illuminating a pattern on a semiconductor wafer comprising:
providing a source of off-axis illumination;
passing the off-axis illumination through at least one opening in a mask;
forming an electric field intensity pattern at the end of the mask, the electric field comprising:
a tapered peak formed by the off-axis illumination passing through the at least one opening in the mask; and
a negative region on either side of the tapered peak by the canceling of and phase reversal of the off-axis illumination scattering off of a dielectric layer found between two metallic layers; and
projecting the electric field pattern formed at the exit of the mask through a projecting system to form a pattern of the mask on to the semiconductor wafer.

19. The method of claim 18 wherein the step of passing the off-axis illumination through at least one opening in the mask further comprises passing the off-axis illumination through a mask having a transparent substrate, a first layer of opaque material formed over the transparent substrate, a second layer of dielectric material formed over the first layer, a third layer of opaque material formed over the second layer and at least one opening.

20. The method of claim 19 wherein the second layer attenuates incident light by acting as an anti-resonance layer.
